(19) United States
(12) Patent Application Publication
(10) Pub. No.: US 2005/0270743 A1
(43) Pub. Date: Dec. 8, 2005

(54) Cooling module for electronic devices

(76) Inventors: Chin Wen Wang, Pingjhen City (TW); Pei Choa Wang, Pingjhen City (TW); Ching Chung Wang, Pingjhen (TW)

Correspondence Address: Yi-Wen Tseng, 4331 Stevens Battle Lane, Fairfax, VA, 22033, US

(21) Appl. No.: 10/858,067

(22) Filed: Jun. 2, 2004

(51) Int. Cl. H05K 7/20

(52) U.S. Cl. 361/699

(57) ABSTRACT

A cooling module is provided for use in an electronic device. The cooling module includes a heat conducting plate, a heat conducting pillar erected on the bottom surface of the heat conducting plate facing a heat generating electronic element, a cooling fin set disposed on the top surface of the heat conducting plate, and an wind mask covering the heat conducting plate and the cooling fin set. An air generator is disposed to one side of the wind mask, and an opening is formed at the other side of the wind mask. Furthermore, a fastening element is formed at two sides of the wind mask for fastening the cooling module onto the housing of the electronic device. Since the housing of the electronic device supports the weight of the cooling module, the heat generating electronic element is prevented from being damaged by the weight of the cooling module.

### BACKGROUND OF THE INVENTION

The present invention relates generally to a cooling module used for an electronic device, and more particularly to a cooling module installed on a heat generating electronic element of the electronic device. The cooling module of the present invention can enhance the heat dissipation rate and reduce the load of the cooling module on the heat generating electronic element.

In the computer industry, faster and faster central processing unit (CPU) has been developed for satisfying the ever-increasing computation demands. As the execution speed of a CPU grows, the heat dissipated therefrom also increases. In order to effectively dissipate the generated heat to the environment so as to maintain the CPU running under a working temperature, a cooling device is usually disposed on the central processing unit to assist heat dissipation of the CPU.

Early cooling device designs includes an aluminum extrusion cooler, which comprises a plurality of extrusively formed aluminum cooling fins. Then, the aluminum extrusion cooler is directly installed on the CPU for cooling the CPU. Later, in order to enhance the heat dissipation rate, a cooling fan is installed above the aluminum extrusion cooler. However, as the execution speed of the CPU increases, the cooling capacitance of the cooling devices mentioned above is still unsatisfactory. Therefore, a heat conducting plate comprising a working fluid and a wick structure are disposed below the aluminum extrusion cooler. The generated heat is thus dissipated through the heat conducting plate.

However, according to what has been discussed above, the conventional cooling devices have been evolved from a simple aluminum extrusion cooler to a cooling device having several elements, such as a cooling fan and a heat conducting plate. Consequently, the weight of the entire cooling device is inevitably increased. If such a cooling device were installed on a CPU, the weight of the cooling device would damage the CPU. Therefore, a new cooling device is demanding.

### BRIEF SUMMARY OF THE INVENTION

In light of the above, the present invention is to provide a cooling module used for an electronic device of a barebone system. The cooling module is disposed in the barebone system for dissipating heat generated by a heat generating electronic element, so as to enhance the heat dissipation rate of the barebone system.

In another aspect, the present invention is to provide a cooling module for use in an electronic device. The cooling module is attached to the housing of the electronic device, so as to reduce the weight suppressed on the heat generating electronic element.

One particular feature of the present invention is in that the cooling module includes a heat conducting plate, a heat conducting pillar erected on the bottom surface of the heat conducting plate facing a heat generating electronic element, a cooling fin set disposed on the top surface of the heat conducting plate, and an wind mask covering the heat conducting plate and the cooling fin set. Furthermore, an air generator is disposed to one side of the wind mask, and an opening is formed at the other side of the wind mask. In this manner, the heat generated by the heat generating electronic element is first transferred to the heat conducting pillar and then to the heat conducting plate, and is exhausted to the environment by employing the cooling fin set and the air generator. The heat dissipation performance of the electronic device is thus enhanced.

Another particular feature of the present invention is in that a fastening element is formed at two sides of the wind mask. When the cooling module is installed in the electronic device, the fastening element fastens the housing of the electronic device. Thus, the weight of the cooling module is supported by the housing of the electronic device, thereby reducing the weight suppressed on the heat generating electronic element.

Yet another particular feature of the present invention is in that a cooling fin set can be disposed on the top surface or the bottom surface, or on both surfaces of the heat conducting plate, thereby enhancing the heat dissipation rate. The air generator includes a fan or a cooling fan. The air generator is disposed at one side of the cooling fin set.

### BRIEF DESCRIPTION OF THE DRAWINGS

FIG. 1 is an explosive view of a cooling module in accordance with the first embodiment of the present invention.

FIG. 2 is a perspective view of the cooling module in accordance with the first embodiment of the present invention.

FIG. 3 is an explosive view of the cooling module used in an electronic device.

FIG. 4 is a perspective view of the cooling module installed on the electronic device.

FIG. 5 is a side sectional view of the electronic device shown in FIG. 4.

FIG. 6 is a front sectional view of the electronic device shown in FIG. 4.

FIG. 7 is a side sectional view of an electronic device in accordance with the second embodiment of the present invention.

FIG. 8 is a front sectional view of the electronic device in accordance with the second embodiment of the present invention.

FIG. 9 is a front sectional view of an electronic device in accordance with the third embodiment of the present invention.

### DETAILED DESCRIPTION OF THE INVENTION

In order to better understanding the features and technical contents of the present invention, the present invention is hereinafter described in detail by incorporating with the accompanying drawings. However, the accompanying drawings are only for the convenience of illustration and description, no limitation is intended thereto.

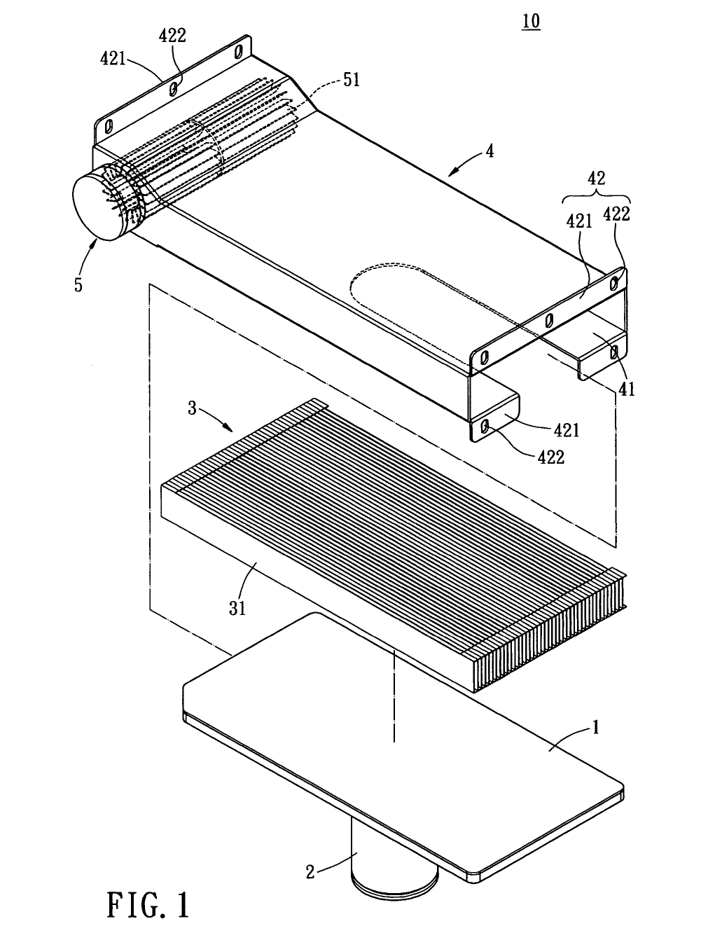

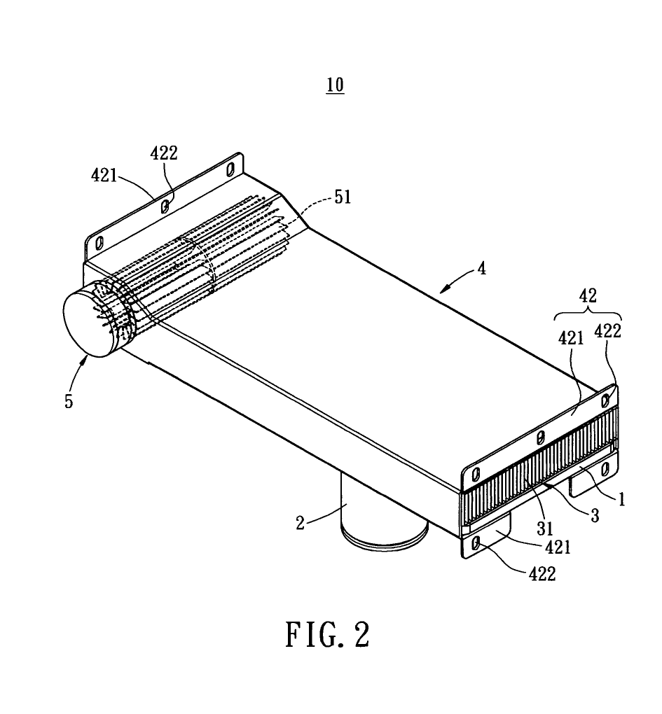

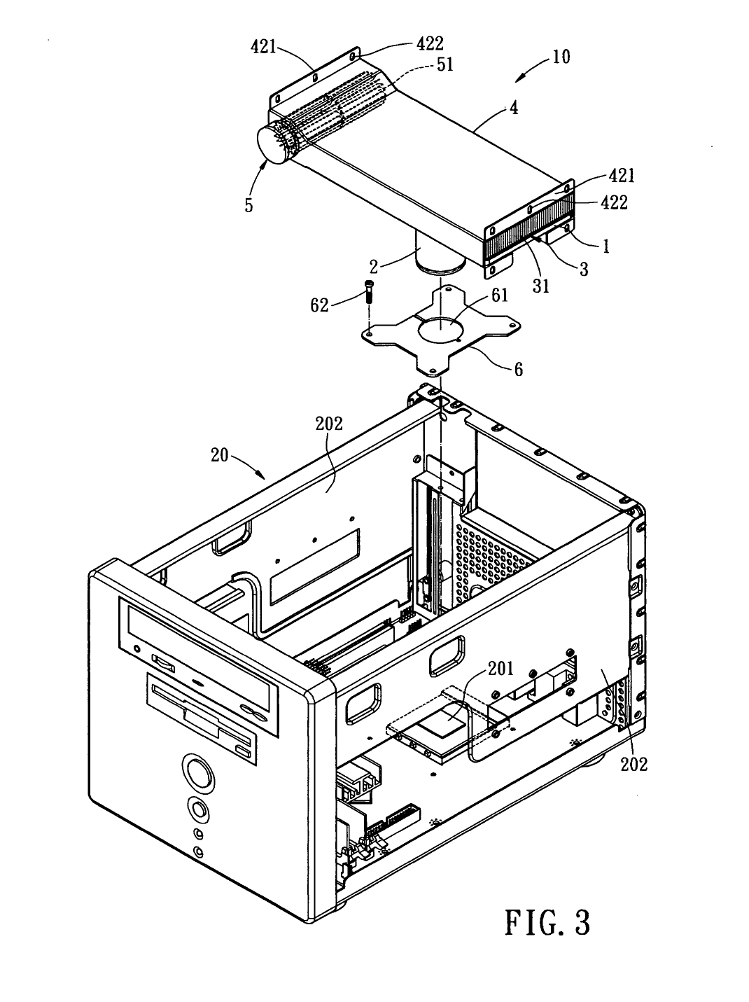

FIG. 1 and FIG. 2 shows a cooling module 10 used for an electronic device, in accordance with the first embodiment of the present invention. As shown in FIG. 3, the cooling module 10 is used in a barebone system 20 so as to dissipate heat generated by a CPU 201 of the barebone system 20. The cooling module 10 includes a heat conducting plate 1, wherein a working fluid and a wick structure are disposed therein. A heat conducting pillar 2 is erected on the bottom surface of the heat conducting plate 1 corresponding to the CPU 201, wherein a working fluid and a wick structure are also disposed therein.

In addition, a cooling fin set is formed at the top surface of the heat conducting plate 1. The cooling fin set includes a plurality of equally spaced cooling fins 31. The cooling fins 31 are horizontally arranged. Also, there is a hollow wind mask 4 containing the heat conducting plate 1 and the cooling fin set 3 therein. An air generator is installed at one side of the hollow wind mask 4, while an opening 41 is formed at the other side of the wind mask 4. In the first embodiment of the present invention, the air generator 5 is a fanner 51. A fastening element 42 is formed at two sides of the wind mask 4, respectively. The fastening element 42 includes a protrusively formed fastening board 421 at the upper and lower rims thereof, wherein a plurality of locking holes 422 is formed on the fastening board 421.

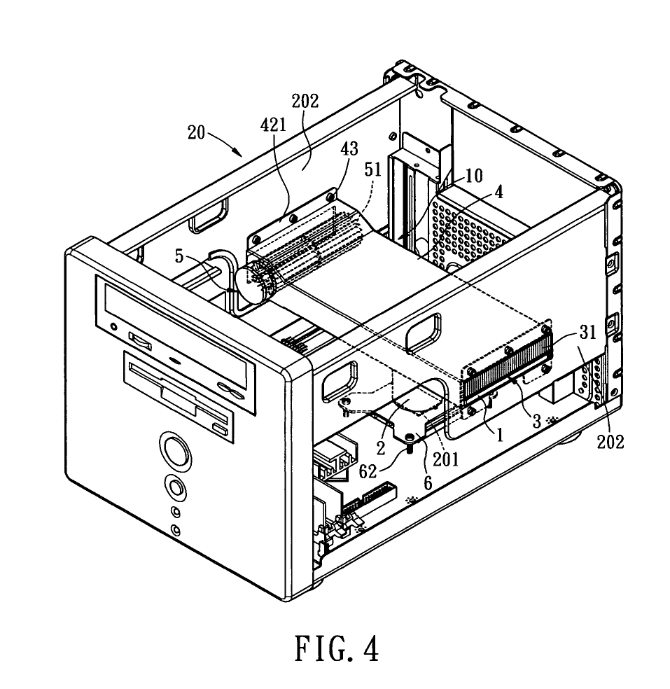

Referring to FIG. 3 and FIG. 4, when installing the cooling module 10 into a barebone system 20, a fastening locking sheet 6 is employed. The fastening locking sheet 6 includes a hole 61 for penetrating the heat conducting pillar 2 of the cooling module 10 therethrough. After disposing the cooling module 10 into the barebone system 20, the fastening locking sheet 6 locks the cooling module 10 on the CPU 201 by applying a plurality of screwing members 62 at the peripherals of the fastening locking sheet 6. The heat conducting pillar 2 is thus disposed on the upper surface of the CPU 201. Later, the fastening boards 421 at two sides of the cooling module 10 are fastened to the corresponding two sides of the housing 202 of the barebone system 20 by employing a plurality of screwing members 43, thereby combining the cooling module 10 with the barebone system 20.

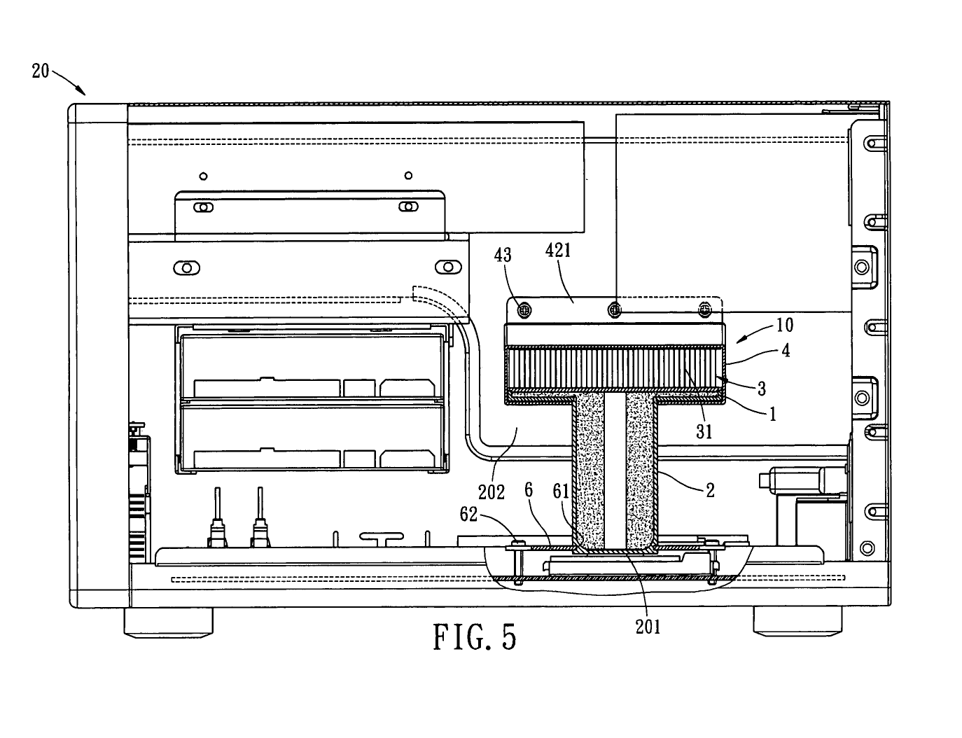

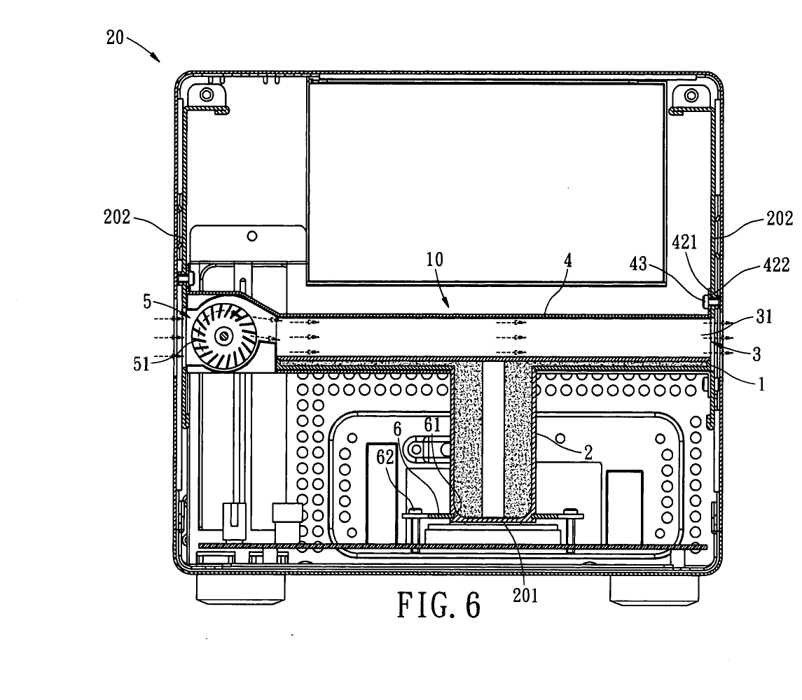

Referring to FIG. 5 and FIG. 6, the heat generated by the CPU 201 is first transferred to the heat conducting pillar 2. The working fluid and the wick structure inside of the heat conducting pillar 2 then perform heat exchange, transferring the heat upward to the heat conducting plate 1. Since there is a heat conducting pillar 2 between the heat conducting plate 2 and the CPU 201, heat generated by other electronic elements adjacent the CPU 201 is also dissipated through the heat conducting plate 1.

Since the temperature of the heat transferred to the heat conducting plate 1 is lowered, the working fluid and the wick structure in the heat conducting plate 1 is employed for further heat dissipation. Since the temperature of the heat is lowered, one can employ the cooling fin set 3 and the cold air generated by the fanner 51 to further lower the temperature of the heat in the cooling fin set 3. Thus, the heat dissipation rate and performance are both enhanced.

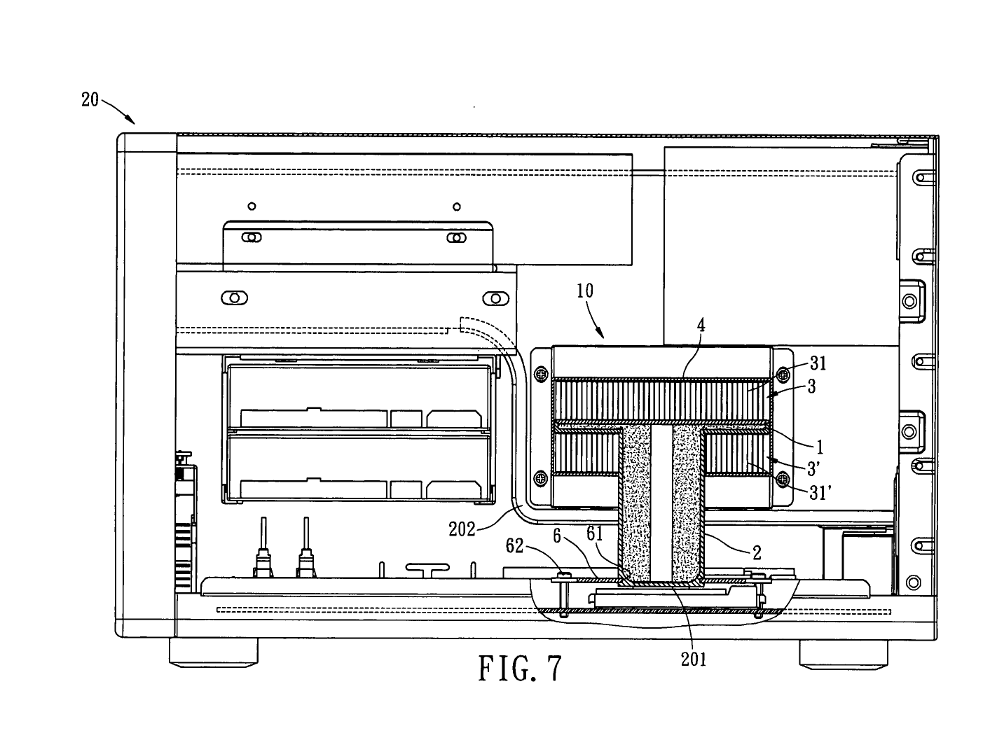

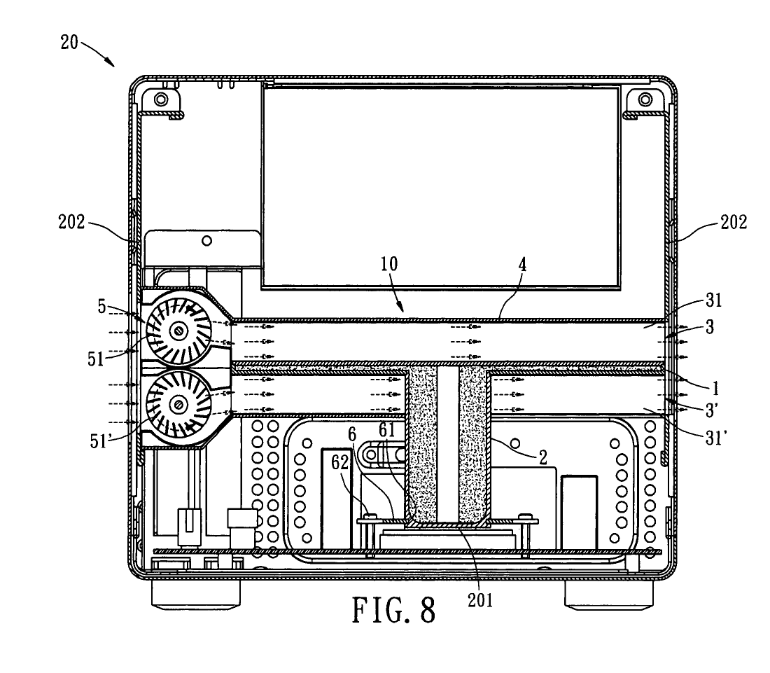

Referring to FIG. 7, an electronic device in accordance with the second embodiment of the present invention is illustrated. Since the heat conducting pillar 2 is disposed between the heat conducting plate 1 and the CPU 201, another cooling fin set 3′ can be disposed to the bottom surface of the heat conducting plate 1, in addition to the cooling fin set 3 disposed to the top surface of the heat conducting plate 1. Correspondingly, referring to FIG. 8, two fanners 51, 51′ are respectively disposed to the sides of the upper and lower cooling fin sets 3, 3′. Therefore, the heat dissipation performance of the cooling module 10 is enhanced.

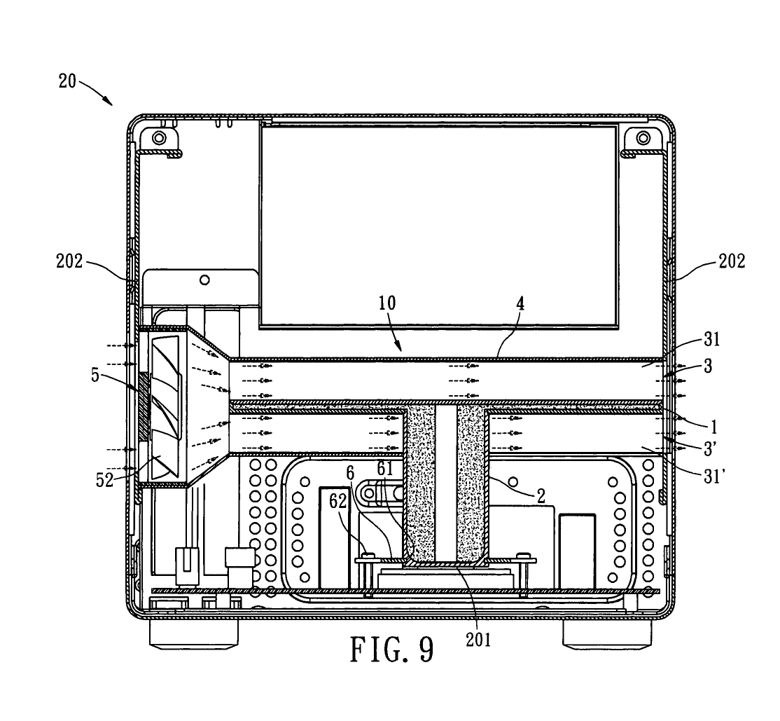

Referring to FIG. 9, an electronic device in accordance with the third embodiment of the present invention is illustrated. The air generator 5 is a cooling fan 52 aiming at the upper and lower cooling fin sets 3, 3′. The cooling fan 52 provides cold air to the two cooling fin sets 3, 3′.

In summary, the cooling module 10 of the present invention transfers heat generated by the CPU 201 first to the heat conducting pillar 2 and then to the heat conducting plate 1. The heat is then exhausted to the environment by employing the cooling fin set 3 and the air generator 5. Thus, the heat dissipation performance of the electronic device 20 is enhanced.

In addition, when the cooling module 10 is installed in the barebone system 20, the cooling module 10 is fastened to the housing 202 of the barebone system 20 by using the fastening element 42. In this manner, the housing 202 can support the cooling module 10, thereby reducing the load of the cooling module 10 disposed on the CPU 201. The CPU 201 is then less likely to be damaged by the weight of the cooling module 10.

Since, any person having ordinary skill in the art may readily find various equivalent alterations or modifications in light of the features as disclosed above, it is appreciated that the scope of the present invention is defined in the following claims. Therefore, all such equivalent alterations or modifications without departing from the subject matter as set forth in the following claims is considered within the spirit and scope of the present invention.

1. A cooling module for cooling a heat generating electronic element of an electronic device, said cooling module comprising:
a heat conducting plate, wherein a working fluid and a wick structure are formed therein;
a heat conducting pillar, erected on the bottom surface of said heat conducting plate and facing the heat generating electronic element, wherein a working fluid and a wick structure is formed in said heat conducting pillar;
a cooling fin set disposed on one side of said heat conducting plate, said cooling fin set comprising a plurality of equally spaced fins;
an wind mask covering said heat conducting plate and said cooling fin set, wherein an air generator is disposed to one side of said wind mask, and wherein an opening is formed at the other side of said wind mask; and
a fastening element formed at one side of said wind mask for fastening said cooling module onto a housing of the electronic device.

2. The cooling module as recited in claim 1, wherein the electronic device is a barebone system, while the heat generating electronic element is a central processing unit.

3. The cooling module as recited in claim 1, wherein said air generator comprises a fanner.

4. The cooling module as recited in claim 1, wherein said air generator comprises a cooling fan.

5. The cooling module as recited in claim 1, wherein said fastening element comprises a plurality of protrusively formed fastening plates at the upper and the lower rims of two sides of said wind mask, said fastening plates comprises a plurality of locking holes.

6. The cooling module as recited in claim 1, further comprising a fastening locking sheet, said fastening locking sheet comprising a hole at the center portion thereof, so as to allow said heat conducting pillar penetrating through the hole, thereby locking said fastening locking sheet around the heat generating electronic device.

7. The cooling module as recited in claim 1, wherein said cooling fin set is disposed on the top surface of said heat conducting plate.

8. The cooling module as recited in claim 1, wherein said cooling fin set is disposed on the top surface and the bottom surface of said heat conducting plate.
